(19) United States
(12) Patent Application Publication
(10) Pub. No.: US 2016/0359185 A1
(43) Pub. Date: Dec. 8, 2016

(54) TWO-LAYER COATINGS ON METAL SUBSTRATES AND DENSE ELECTROLYTE FOR HIGH SPECIFIC POWER METAL-SUPPORTED SOFC

(71) Applicant: Ballard Power Systems Inc., Burnaby (CA)

(72) Inventors: Jean Yamanis, South Glastonbury, CT (US); TianIi Zhu, Cheshire, CT (US); Neal Magdefrau, Tolland, CT (US); Mark A. Hermann, Glastonbury, CT (US)

(21) Appl. No.: 15/242,327

(22) Filed: Aug. 19, 2016

Related U.S. Application Data
(62) Division of application No. 14/269,482, filed on May 5, 2014.
Application No. 14/269,482 is a continuation of application No. 13/100,486, filed on May 4, 2011, now abandoned.
(60) Provisional application No. 61/330,924, filed on May 4, 2010.

(51) Int. Cl. H01M 8/1286; C23C 14/08; H01M 8/1253; C23C 14/30; H01M 8/1226; H01M 8/126

(52) U.S. Cl. CPC H01M 8/1286; H01M 8/1226; H01M 8/126; H01M 8/1253; C23C 14/30; C23C 14/083; C23C 14/08; H01M 2008/128

(57) ABSTRACT

A fuel cell includes a chromium-containing metal support, a ceramic electrode layer on the metal support and an electroconductive ceramic layer between the chromium-containing metal support and the ceramic electrode layer. The electroconductive ceramic layer includes a ceramic material selected from lanthanum-doped strontium titanate and perovskite oxides.

### FIELD

This disclosure generally relates to metal-supported solid oxide fuel cells.

### BACKGROUND

Solid oxide fuel cells are commonly known and used for generating electricity. For example, conventional solid oxide fuel cells typically include a ceramic anode, a ceramic cathode, and an ion-conducting ceramic oxide electrolyte between the anode and the cathode. A metal support structure mechanically supports the anode, the cathode, and the electrolyte. The support structure may also serve to supply reactant gas to the electrodes and conduct electric current to an external circuit.

Processing the ceramic materials requires sintering at relatively high temperatures (>1000° C./1832° F.). Despite process controls, the high sintering temperature oxidizes the metal support to create an oxide scale at the interface between the metal support and the ceramic material of the anode, for example. The oxide scale increases ohmic resistance and thereby diminishes performance of the fuel cell.

### SUMMARY

Disclosed is a fuel cell that includes a chromium-containing metal support, a ceramic electrode layer on the metal support, and an electroconductive ceramic layer between the chromium-containing metal support and the ceramic electrode layer. The electroconductive ceramic layer includes a ceramic material selected from lanthanum-doped strontium titanate and perovskite oxides.

In another aspect, the electroconductive ceramic layer between the chromium-containing metal support and the ceramic electrode layer limits oxidation of the chromium-containing metal support.

Also disclosed is a method of processing a fuel cell. The method includes depositing a dense ceramic electrolyte layer on the ceramic electrode layer. In one example, the dense ceramic electrolyte layer is deposited using ion-assisted electron beam physical vapor deposition.

### BRIEF DESCRIPTION OF THE DRAWINGS

FIG. 1 illustrates an example metal-supported solid oxide fuel cell.

FIG. 2 illustrates a schematic cross-section of an example rigidized foil support.

FIG. 3 illustrates a top view of a completed, 50×80 millimeter, rigidized foil support.

FIG. 4 illustrates a photomicrograph of a cross-section of an example bilayer ceramic structure.

FIG. 5 illustrates a chromia scale at a rigidized foil support/anode interface after sintering of anode layers at relatively high temperature in humidified atmospheres.

FIG. 6 illustrates a chromia scale grown on a rigidized foil support coupon.

FIG. 7 illustrates the electrical impedance of the oxide scale of FIG. 6.

FIG. 8 illustrates an example ferritic stainless sheet that shows no oxidation after heat treatment.

FIG. 9 illustrates an oxide scale at a metal/GDC interface.

FIG. 10 illustrates a lack of oxidation at a metal/LST interface.

FIG. 11 schematically illustrates an example ion-assisted physical vapor deposition process.

FIG. 12 illustrates a photomicrograph of a gadolinia-doped ceria coating deposited by ion-assisted physical vapor deposition.

FIG. 13 illustrates a photomicrograph of a fracture surface of gadolinia-doped ceria coating deposited by ion-assisted physical vapor deposition.

FIG. 14 illustrates a photomicrograph of GDC deposited on a porous ceramic substrate by ion-assisted physical vapor deposition.

FIG. 15 illustrates a photomicrograph of a dense coating of 10 mol % scandia- and 1 mol % ceria-doped stabilized zirconia [(Sc₂O₃)_{0.1}(CeO₂)_{0.01}ZrO_{2-δ}] (ScSZ) deposited by ion-assisted physical vapor deposition in plan-view.

FIG. 16 illustrates the coating of FIG. 15 in cross-section view.

### DETAILED DESCRIPTION OF THE PREFERRED EMBODIMENTS

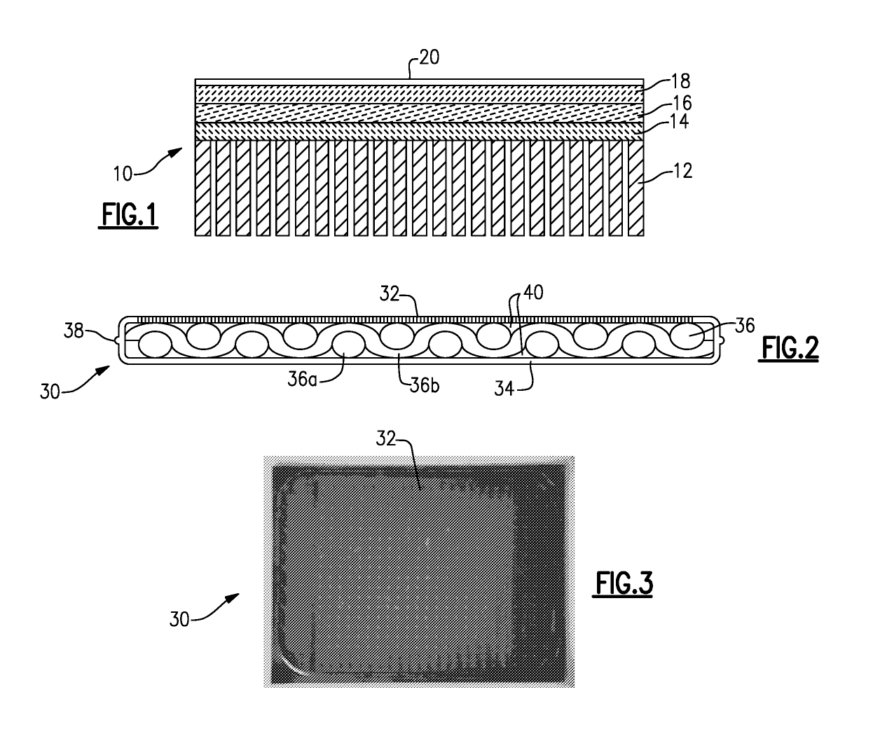

FIG. 1 schematically illustrates selected portions of an example metal-supported solid oxide fuel cell (“SOFC”) 10. Due to the arrangement and processing, as will be described below, the SOFC 10 exhibits very high specific power, operating temperatures of less than 700° C./1292° F., very fast heat-up capability, robustness to thermal cycling and excellent performance stability. The SOFC 10 also exhibits very high gravimetric (specific power) and volumetric (power density) power.

The SOFC 10 generally includes a metal support 12, such as a perforated metal substrate that includes holes for gas transport, a first ceramic layer 14 adjoining the metal support 12, a second ceramic layer 16 adjoining the first ceramic layer 14, a ceramic electrolyte 18 adjoining the second ceramic layer 16, and a third ceramic layer 20 adjoining the ceramic electrolyte 18. Although these elements are functionally required for operation of the SOFC 10, the SOFC 10 need not be provided as a complete product and in some example is provided as an intermediate product without one or more of the elements.

The first ceramic layer 14 serves as an electronic conductor, the second ceramic layer 16 serves as the anode electrode of the SOFC 10, and the third ceramic layer 20 serves as the cathode electrode of the SOFC 10. The first ceramic layer 14 and the second ceramic layer 16 are deposited onto the metal support 12 by wet processing and sintering without oxidizing the metal support 12. The first ceramic layer 14, functions as a barrier to interdiffusion of metal elements between the metal support 12 and the metal phase of the second ceramic layer 16 after reduction of transition metal oxides. The first ceramic layer 14 is therefore considered to be a ceramic barrier layer in addition to being an electronic conductor.

The metal support 12 of the SOFC 10 is what is referred to as a rigidized foil support (RFS), which includes a metallic structure fabricated from metal foils and wire mesh. For example, the metal is ferritic stainless steel, Fe—Cr stainless steels, ITM (a Plansee AG of Austria alloy), Ni—Cr alloys, Inconel, Hastelloy, Haynes, other superalloy material, or other suitable alloy.

FIG. 2 illustrates a schematic cross-section of an example RFS 30, which includes a perforated metal foil 32 and a solid metal foil 34 that each have a thickness of about 50 micrometers. Wires 36a and 36b form a porous reinforcing wire mesh 36 between the metal foils 32 and 34. The wire mesh 36 includes voids or spaces 40 and in one example is constructed of about 2 wires per 5 millimeters (10 mesh) with a wire diameter of about 250 micrometers.

The perforated foil 32 in one example is fabricated from a solid foil by drilling using a suitable metal drilling process, such as laser drilling or etching and other processes known in the art. The RFS 30 is then fabricated by sandwiching the wire mesh 36 with the perforated and solid foils 32 and 34 and diffusion bonding the structure by heating it at temperatures of 900 to 1100° C. (1652 to 2012° F.) under a stress of approximately 25 to 150 kPa.

After the bonding operation, the RFS 30 can be sealed around the periphery by welding to seal the structure 38 at its outer perimeter. Other geometrical designs and parts of different thickness or other dimensions are options of the same concept. The total thickness of the RFS 30 is approximately 0.6 mm. The RFS 30 is designed to support the ceramic layers, with the anode electrode being in fluid communication with the perforated foil 32 and the fuel stream flowing by means of diffusion through the voids 40 of the RFS 30.

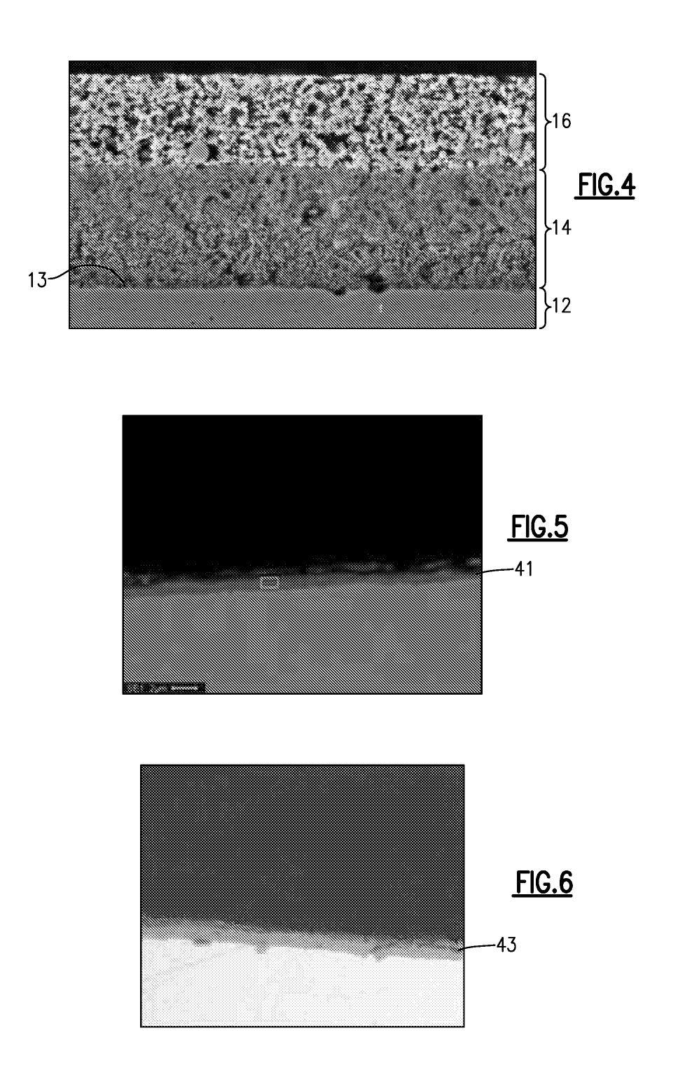

Rigidized foil support structures have been fabricated in a 25 millimeter diameter circular shape, and 50×80 millimeter and 50×300 millimeter rectangular shapes, for example. A top view of a completed, 50×80 millimeter RFS 30 is shown in FIG. 3. The light 50×50 millimeter area in the center is the perforated foil 32. The ceramic layers 14-20 will cover the perforated foil 32 (from the perspective of FIG. 3). The anode electrode ceramic layer 16 is somewhat larger, in each dimension, than the area of the perforated foil 32 to cover all the holes. The electrolyte coating ceramic layer 18 is somewhat larger, in each dimension, than the area of the anode electrode ceramic layer 16 so that the ceramic layer 18 seals the edge of the ceramic layer 16 all around the periphery.

The first ceramic layer 14 in one example is a non-reducible electronic conductor ceramic oxide, which in some examples is a single or multi-element oxide. The second ceramic layer 16 in one example is NiO-GDC (gadolinium-doped ceria), NiO-ZrO₂, Cu-oxide/GDC, Cu-oxide/ZrO₂, Ni—Cu-oxides/GDC or ZrO₂, wherein ZrO₂ stands for partially or fully stabilized zirconia.

The first ceramic layer 14 provides an electronic conduction path from the second ceramic layer 16 to the metal support 12 and acts as a barrier between the metal support 12 and the metal phase that forms after reduction of the second ceramic layer 16 (the anode electrode of the SOFC 10). The barrier facilitates mitigating or eliminating metal element interdiffusion between the metal support 12 and the metal phase of the second ceramic layer 16, which leads to improved performance and durability.

In general, the arrangement of the metal support 12/first ceramic layer 14/second ceramic layer 16 enables sintering the precursor to the second ceramic layer 16 (thickness approximately 15 micrometers) on the metal support 12 at temperatures of less than 1100° C./2012° F., without oxidizing the metal support 12, which would otherwise have an oxide scale that increases ohmic resistance at the metal/ceramic interface.

The ability to sinter the precursor to the second ceramic layer 16 on the metal support 12 at temperatures less than 1100° C./2012° F., without oxidizing the metal support 12, is achieved by using the bilayer structure of the first ceramic layer 14 and the second ceramic layer 16. The first ceramic layer 14, which is in contact with the metal support 12, in one example is a lanthanum-doped strontium titanate (“LST”), LaₓSr₁₋ₓTiO_{3-δ}, which is expected to act as an electron conductor. The first ceramic layer 14 in one example is selected from the group of perovskite oxides (ABO₃), such as lanthanum manganite and lanthanum chromite, doped with divalent cations on the A site that are known to be stable in a reducing or fuel atmosphere. The second ceramic layer 16 in one example is a composite of NiO with gadolinium doped ceria (“GDC”), Ce₁₋ₓGdₓO_{2-δ}, which is the precursor of the anode electrode (Ni/GDC) in the SOFC 10.

The first ceramic layer 14 and the second ceramic layer 16 in one example are deposited on the metal support 12 sequentially using a known suitable ceramic process, such air brushing, screen printing, doctor blade, etc., followed by drying, binder burn-out and finally sintering in a furnace under controlled atmosphere that ensures absence of molecular oxygen. Alternative processes that do not lead to metal oxidation may be used and they would not be beyond the scope of the present disclosure. Examples of such alternative processes for depositing the two ceramic layers on the metal are chemical vapor deposition, sputtering, plasma spray, electron beam physical vapor deposition, and ion-assisted physical vapor deposition (or IBAD).

The following compositions of LST and GDC are used in some examples, and similar behavior is expected with a variety of other stoichiometric compositions and dopant elements: La_{0.35}Sr_{0.65}TiO_{3-δ}and Gd_{0.1}Ce_{0.9}O_{2-δ}.

FIG. 4 illustrates a photomicrograph of a cross-section of an example bilayer ceramic structure made by wet ceramic processing and subsequent sintering on the metal support 12 according to the examples herein, without metal oxidation at the interface 13. The photomicrograph does not show any chromium oxide formation at the interface between the metal support 12 and the first ceramic layer 14 (LST layer). The absence of chromium oxide at this interface has also been documented by EDS line scans across the interface and Auger analysis.

Reference Examples of Metal Oxidation

The improvement of avoiding metal oxidation at the interface between the metal support 12 and the first ceramic layer 14 in the above examples is further evident from several design experiments on a conventional SOFC having the ceramic electrode layer directly on the metal support. For instance, a chromia scale was detected at the RFS/anode interface after sintering developmental anode layers at relatively high temperature (1000° C./1832° F.) in humidified (˜3% H₂O) 97% Ar-3% H₂ atmospheres, meaning Argon humidified with ˜3% water is 97% of the total gas mixture, and long processing time (4 hours). The scale 41 is nominally 1 micron thick, as shown in FIG. 5.

Chromia scales were grown on a 2×2 centimeter RFS coupon by exposure to a humidified 95% N₂, 5% H₂ (approximately 3% water vapor in the gas stream) furnace atmosphere at 1000° C./1832° F. for four hours. These conditions were chosen to conservatively represent the furnace cycles used to sinter the anode electrode layer and electrolyte screen printed and sealing layers. The oxide scale 43 produced under these conditions is approximately three microns thick, as shown in FIG. 6.

Potentiostatic impedance measurements were also made using a 1 cm² fine Pt mesh electrode, with an estimated scale contact area of 1%. A static load of 15 g was applied to the mesh using alumina plates. Impedance spectra were collected in air over a temperature range from 745 to 1190° C. (1373 to 2174° F.). At temperatures above 250° C./482° F., a 10 mV amplitude sine wave signal was used. Below 250° C./482° F., a 100 mV sine wave signal was used for improved resolution. The impedance values at 1 Hz were found to provide a good representation of the DC limit, and were used to assess the resistance of the chromia scale as a function of temperature, as shown in FIG. 7. As shown in FIG. 7, at an SOFC operating temperature of 600° C./1112° F., the resistance of the scale area contacted by the mesh electrode is of the order of 10⁵ Ω. Applying an estimate of 1% mesh contact area yields an estimated ASR of the chromia scale of 10³ Ω·cm². This value far exceeds a desired limit of 0.1 Ω·cm².

Mitigation of Metal Oxidation

Metal oxidation can generally be avoided via processing metal coupons in a tube furnace that is purged for sufficiently long time (for example, purging at 1 liter/min for 4 hours with or without prior evacuation) with a high purity argon (Ar) stream and adding the use of an oxygen getter, e.g., titanium foils, in the furnace at strategic locations, such as the upstream end of the tube and around the metal samples. Under the aforementioned conditions metal oxidation is eliminated on free surfaces. The image in FIG. 8 shows an example ferritic stainless sheet (Crofer 22 APU) that shows no oxidation after heat treatment at 1000° C./1832° F. for 10 hours in a tube furnace with the processing protocol as described.

Metal Oxidation at the Metal/GDC Interface

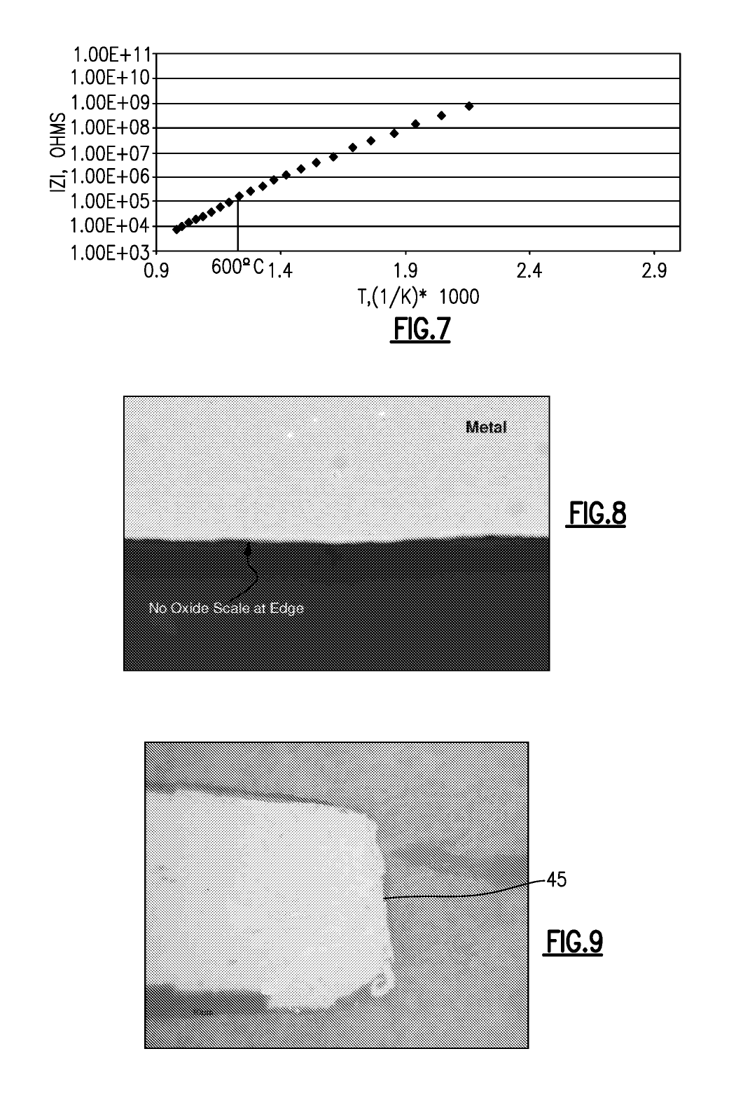

In contrast to the avoidance of oxidation of the metal coupons, Crofer 22 APU, a ferritic stainless steel, oxidizes when in contact with gadolinium-doped ceria. For example, Crofer 22 APU was placed in contact with gadolinium-doped ceria (10GDC), and the assembly was heat treated at 1000° C./1832° F. in a tube purged with argon and in the presence of an oxygen getter as described above. Under these conditions, the metal develops an oxide scale 45 at the metal/GDC interface as shown by the dark areas in the micrographs shown in FIG. 9. The scale formation at the metal/GDC interface is likely to arise from the reduction of ceria by the ferritic stainless steel constituent elements and, in particular, chromium. Nevertheless, and whatever the actual physical mechanism may be, the oxide scale forms when 10GDC particles are in contact with the metal, under what are considered to be carefully controlled atmospheres that normally avoid oxidation, i.e., atmospheres devoid of molecular oxygen, and the assembly is heat treated at high temperature. The phenomenon is expected to take place for pure ceria as well as ceria doped with other elements and arises from the well-known reducibility of ceria.

No Metal Oxidation at the Metal/LST Interface

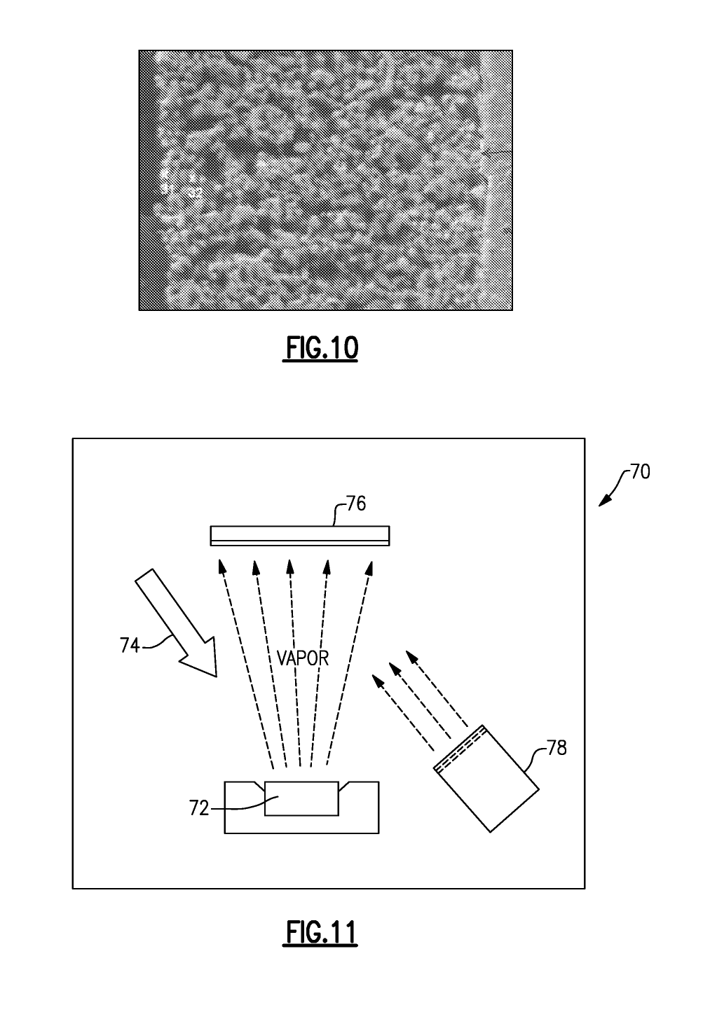

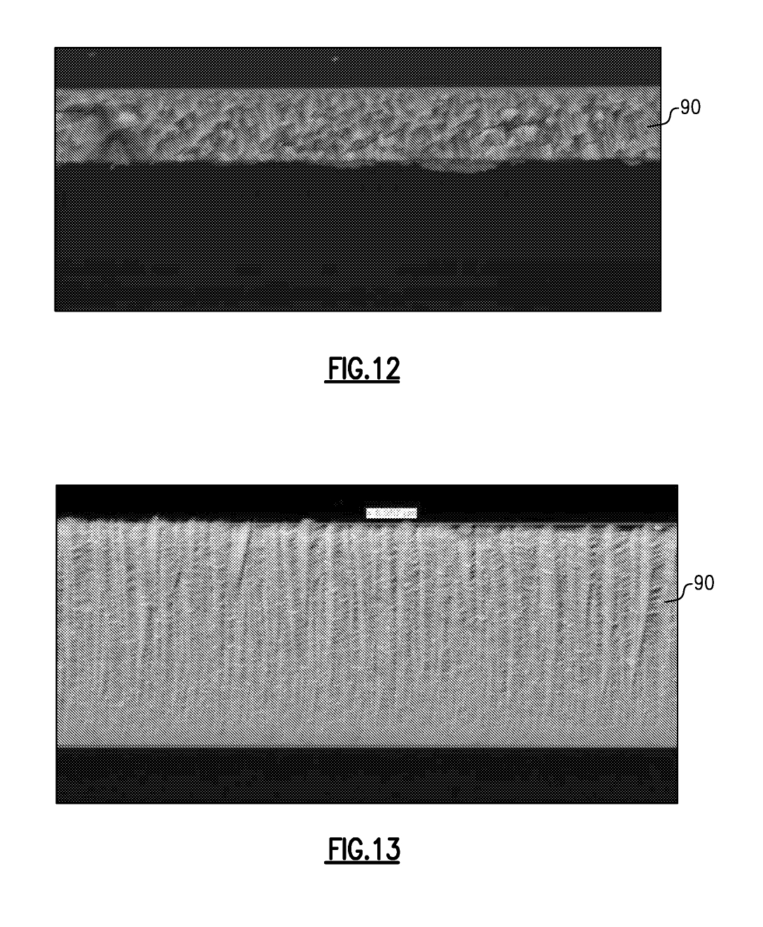

In contrast to the above oxidation that forms when a ferritic stainless steel is in contact with the oxide gadolinium-doped ceria, the metal in contact with the first ceramic layer 14 does not oxidize in the SOFC 10 when Crofer 22 APU, a ferritic stainless steel, is placed in contact with lanthanum-doped strontium titanate (La_{0.35}Sr_{0.65}TiO_{3-δ}) and the assembly is heat treated at 1000° C./1832° F. in a tube purged with argon and in the presence of an oxygen-getter as described above. That is, the metal does not form an oxide scale that would introduce resistance to the flow of electrons. The micrograph in FIG. 10 shows the lack of oxidation of the metal by LST.

Since LST is a good electronic conductor and heat treating a metal coated with LST does not lead to the formation of an oxide scale, LST is used as the first ceramic layer 14 in the SOFC 10 of one example and acts as the support for the NiO/GDC precursor to the second ceramic layer 16. After activation of the anode precursor, i.e., after reduction of the NiO to Ni metal and under fuel cell operating conditions, electrons released at the electrolyte/anode electrode interface by the simultaneous oxidation of fuel, i.e., hydrogen, the electrons would travel through the Ni phase in the anode electrode, then through the LST layer and from there into the metal support 12 and beyond without having to cross a high ohmic resistance area.

The SOFC 10 in one example is further processed to deposit the ceramic electrolyte 18, which in one example is an oxide ion conductor at layer thicknesses as low as 5 micrometers. For instance, the ceramic electrolyte 18 is any type of solid oxide electrolyte, such as ceria (CeO₂) doped with rare earth metal oxide(s), gallate (e.g., strontium-doped lanthanum gallate), or stabilized (fully or partially) zirconia. In further examples, the oxide ion conductor material is gadolinia-doped ceria or scandia-doped zirconia. The ceramic electrolyte 18 is deposited in a fully dense state on the porous ceramic substrates of the second ceramic layer 16, or even directly onto a metal substrate in thicknesses as low as 3 μm. As an example, ion-assisted electron beam physical vapor deposition is used to deposit the ceramic electrolyte 18.

FIG. 11 schematically illustrates an example ion-assisted physical vapor deposition process 70 for depositing the dense layer of ceramic oxide material. The process 70 may be referred to as Ion Beam Assisted Deposition (“IBAD”). The IBAD process 70 utilizes a target material 72 to be deposited. The target material 72 is heated by an electron beam energy source 74 to melt the target material 72, from which atoms of the elements of the target material 72 evaporate (neutral atoms) and diffuse toward the substrate 76.

The substrate 76 may be the second ceramic layer 16, another ceramic material, or a metal material, depending on the end use of the component being fabricated. The substrate 76 is maintained at a relatively low temperature on which the evaporated target material 72 deposits to form a thin film of material having a composition essentially the same as that of the target material 72. The thin film is the ceramic electrolyte 18 in the SOFC 10.

An ion source 78 generates a stream of ions that bombard the evaporated atoms, which energizes the atoms to impact the substrate 76. The high-energy atoms that impact the substrate 76 form the thin film with a desirably high density. Ions of inert (e.g., argon) or reactive elements (e.g., oxygen) are used in some examples for the ion beam.

The substrate 76 in one example is a material that is substantially pore-free, such as a metal, or a porous material, such as a porous ceramic (e.g., the second ceramic layer 16). The IBAD process parameters, such as electron beam energy and ion beam current, is controlled to yield thin films of oxide-ion conducting ceramic oxides on porous ceramic substrates. Additionally, the element used as the ion beam is selected to compliment the deposition process. An inert element, such as argon, is selected to avoid influencing the composition of the thin film and a reactive element, such as oxygen, is used to influence the composition of an oxide in the thin film (e.g., to control stoichiometry).

In the case of the SOFC 10, it is desirable that the ceramic oxide-ion conducting material of the ceramic electrolyte 18 is substantially or entirely free of open porosity. The IBAD process 70 enables depositing a fully dense ceramic oxide-ion conducting material on the porous second ceramic layer 16.

Dense coatings of gadolinia-doped ceria (10GDC) and scandia-doped zirconia were deposited on pore free and porous substrates at coating thicknesses as low as 3 micrometers, thus meeting the above requirement. The application of dense oxide-ion conducting ceramic oxide films has been achieved by utilizing the IBAD process 70 at substrate temperatures as low as 300° C./572° F.

Examples of Dense Oxygen-Conducting Ceramic Coatings

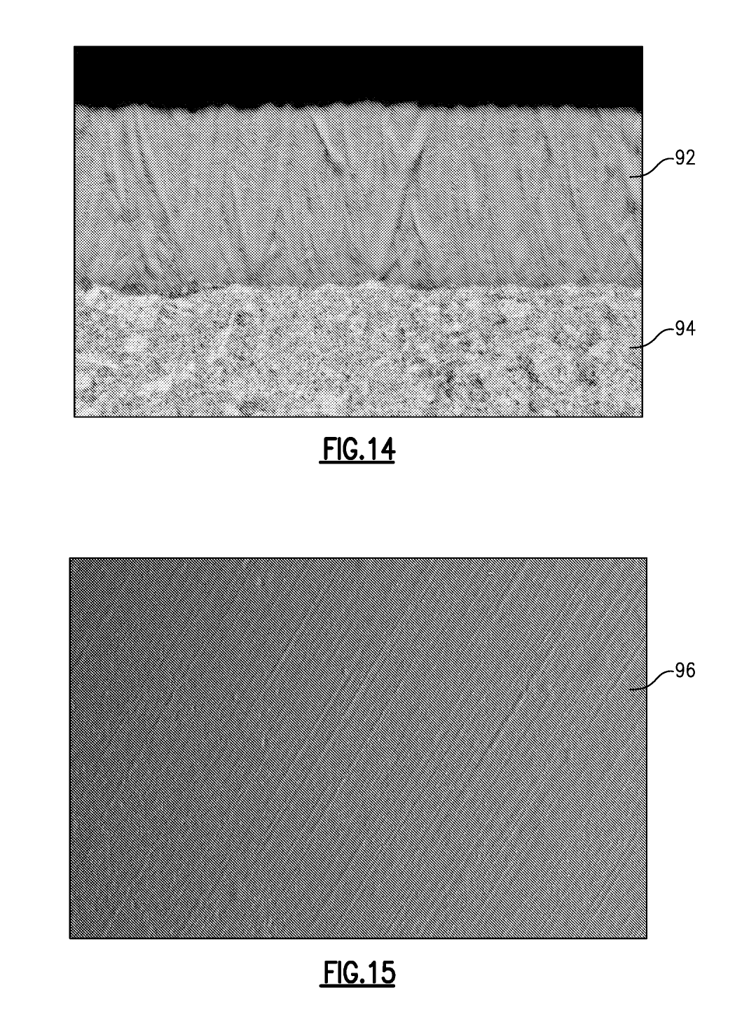

FIG. 12 shows a photomicrograph of a gadolinia-doped ceria coating 90, or thin film, in which the coating 90 is fully dense even at the very low thickness of about 7 micrometers.

FIG. 13 shows a photomicrograph of a fracture surface of gadolinia-doped ceria coating 90 having a thickness of about 7 micrometers. This coating was applied on an alumina substrate that could be fractured to prepare the specimen for observation.

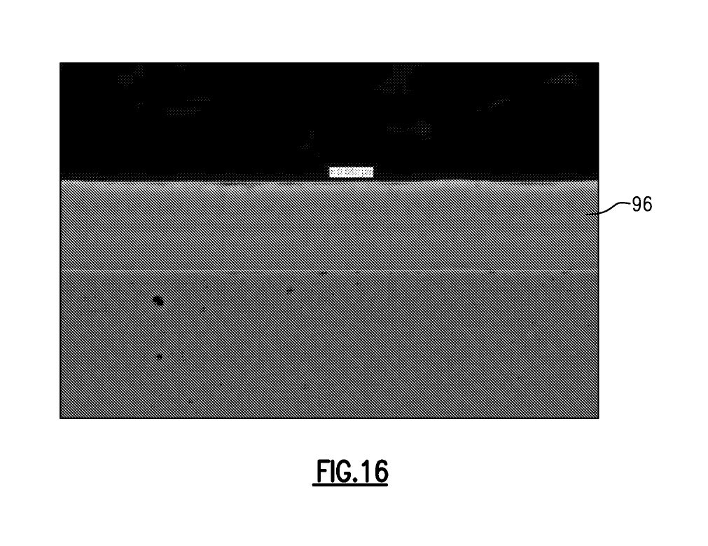

FIG. 14 shows a photomicrograph of GDC 92 on a porous ceramic substrate 94. The coating is about 10 micrometers thick and dense. Thus the IBAD process 70 is used to deposit coatings that bridge pores of significant (˜1 micrometers) size. The porous substrate in this micrograph simulates a porous anode electrode. For the coating to be an effective electrolyte layer it must be free of open porosity and be supported by a porous anode electrode so that the fuel can reach the anode/electrolyte interface for the electrochemistry to occur.

FIG. 15 shows a photomicrograph of a dense coating 96 of 10 mol % scandia and 1 mol % ceria-doped stabilized zirconia [(Sc₂O₃)_{0.1}(CeO₂)_{0.01}ZrO_{2-δ}] (ScSZ), which is illustrated in cross-section in FIG. 16. The coating 96 is very dense and essentially free of defects.

Other processes besides IBAD, such as MOCVD, pulsed laser deposition, radio frequency sputtering, large area filtered arc deposition etc., could be used to deposit dense electrolyte coatings on porous substrates.

Although a combination of features is shown in the illustrated examples, not all of them need to be combined to realize the benefits of various embodiments of this disclosure. In other words, a system designed according to an embodiment of this disclosure will not necessarily include all of the features shown in any one of the Figures or all of the portions schematically shown in the Figures. Moreover, selected features of one example embodiment may be combined with selected features of other example embodiments.

The preceding description is exemplary rather than limiting in nature. Variations and modifications to the disclosed examples may become apparent to those skilled in the art that do not necessarily depart from the essence of this disclosure. The scope of legal protection given to this disclosure can only be determined by studying the following claims.

What is claimed is:

1. A method comprising:
forming an electroconductive ceramic layer on a porous metal support;
forming a ceramic anode layer on the electroconductive ceramic layer;
forming a ceramic electrolyte layer on the ceramic anode layer; and
forming a ceramic cathode layer on the ceramic electrolyte layer.

2. The method as recited in claim 1, wherein:
forming the electroconductive ceramic layer comprises sintering the electroconductive ceramic layer;
forming the ceramic anode layer comprises sintering the ceramic anode layer; and
forming the ceramic electrolyte layer comprises using ion-assisted electron beam physical vapor deposition to deposit the ceramic electrolyte layer on the ceramic anode layer.

3. A method of limiting oxidation of a chromium-containing metal support in a fuel cell, the method comprising:
using an electroconductive ceramic barrier layer between a chromium-containing metal support and a ceramic electrode layer disposed on the chromium-containing metal support, the electroconductive ceramic barrier layer including a ceramic material selected from a group consisting of lanthanum-doped strontium titanate and perovskite oxides.

4. A method of processing a fuel cell, the method comprising:
providing a substrate that includes:
a chromium-containing metal support;
a ceramic electrode layer on the metal support; and
an electroconductive ceramic layer between the chromium-containing metal support and the ceramic electrode layer, the electroconductive ceramic layer includes a ceramic material selected from a group consisting of lanthanum-doped strontium titanate and perovskite oxides; and
depositing a dense ceramic electrolyte layer on the ceramic electrode layer.
